(19) United States
(12) Patent Application Publication
(10) Pub. No.: US 2015/0351288 A1
(43) Pub. Date: Dec. 3, 2015

(54) ELECTRONIC APPARATUS AND FILTER DEVICE

(71) Applicant: FUJITSU LIMITED, Kawasaki-shi (JP)

(72) Inventor: Takashi Fukuda, Kawasaki (JP)

(73) Assignee: FUJITSU LIMITED, Kawasaki-shi (JP)

(21) Appl. No.: 14/632,153

(22) Filed: Feb. 26, 2015

(30) Foreign Application Priority Data
May 29, 2014 (JP) 2014-111465

(51) Int. Cl. H05K 7/20; B01D 46/00

(52) U.S. Cl. CPC H05K 7/20736; B01D 46/0019; B01D 46/0075; B01D 46/0065

(57) ABSTRACT

An electronic apparatus includes a housing including an opening, an object to be cooled that is disposed in the housing, an air flow generation unit that generates cooling air which flows through the opening into the housing and flows to the object to be cooled, a plurality of filter units that remove a foreign matter contained in the cooling air, a blocking unit that blocks at least one filter unit to be cleaned, among the filter units, a controller that increases a flow rate of the cooling air using the air flow generation unit, and a cleaning processing unit that cleans the filter unit to be cleaned, the filter unit to be cleaned being blocked by the blocking unit.

### CROSS-REFERENCE TO RELATED APPLICATION

This application is based upon and claims the benefit of priority of the prior Japanese Patent Application No. 2014-111465, filed on May 29, 2014, the entire contents of which are incorporated herein by reference.

### FIELD

The embodiment discussed herein is related to an electronic apparatus and a filter device.

### BACKGROUND

In general, in an information processing device such as a storage device, heat generated at the time of operation of the device is cooled by forced air cooling using cooling fans. In such a device equipped with cooling fans, a filter mounted in a front bezel for example, protects the device against intrusion of foreign matters carried by air flow generated by the cooling fans.

However, with the passage of operation time of the device, foreign matters accumulate in the filter and cause clogging. When the filter is clogged, cooling efficiency decreases and unfavorable condition such as temperature rise occurs in the device. Thus, regular cleaning of the filter may be performed.

In an information processing device of the conventional technique when a filter is clogged, the problem is handled by replacing or cleaning the filter with manual operation of a maintenance worker.

Related techniques are disclosed in, for example, Japanese Laid-open Patent Publication Nos. 2000-291999, 2001-182958, and 2000-354720.

However, in such an information processing device of the conventional technique after a filter is clogged, a maintenance worker replaces or cleans the filter manually, and so the maintenance worker may be unable to start working to alleviate the clogging immediately after the occurrence of the clogging. Therefore, the temperature of the device may rise due to the clogging of the filter.

An information processing device such as a storage device is used also for a mission critical task for which the device is normally not allowed to be stopped. For example, in such a storage device used for a mission critical task, reading and saving of client data are performed all the time.

It is often the case that such a storage device used for a mission critical task is installed in a special environment called a computer room. In a computer room, a great number of servers and storage devices are installed. In order to achieve stable operation of these devices in a great number, air conditioning in the computer room has stronger setting than that in a normal office environment, and the computer room is designed to have active air circulation. However, unlike a clean room where semiconductors are manufactured, dust protection measures are not particularly taken for a computer room, and thus the computer room inevitably contains more dirt and dust from the outside than in a normal office environment. For this reason, it is inevitable that dirt and dust intrude into the devices.

In such an information processing device that is disposed in a computer room to be used for a mission critical task, a relevant filter is replaced or cleaned with the device in operation, and so while a maintenance worker cleans the filter, the device is without the filter mounted. When the device is operated without a filter mounted like this, a foreign matter may intrude into the device and may cause a failure of the device.

As an approach of reducing the time of cleaning in order to shorten time during which the device is without a filter mounted, it is conceivable that the entire front bezel be replaced. However, replacing the front bezel for each event of filter clogging increases the maintenance cost and thus is not practical.

An aspect of the present disclosure provides a device that allows a filter to be cleaned with the device in operation while protecting against intrusion of foreign matters.

### SUMMARY

According to an aspect of the invention, an electronic apparatus includes a housing including an opening, an object to be cooled that is disposed in the housing, an air flow generation unit that generates cooling air which flows through the opening into the housing and flows to the object to be cooled, a plurality of filter units that remove a foreign matter contained in the cooling air, a blocking unit that blocks at least one filter unit to be cleaned, among the filter units, a controller that increases a flow rate of the cooling air using the air flow generation unit, and a cleaning processing unit that cleans the filter unit to be cleaned, the filter unit to be cleaned being blocked by the blocking unit.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a perspective view schematically illustrating the appearance of an exemplary electronic apparatus according to an embodiment;

FIG. 2 is an exploded perspective view schematically illustrating the internal configuration of the exemplary electronic apparatus according to the embodiment;

FIG. 3 is a side view of the exemplary electronic apparatus according to the embodiment;

FIG. 4 is a diagram illustrating the functional configuration of a controller in the exemplary electronic apparatus according to the embodiment;

FIG. 5 is a perspective view illustrating the appearance of a front bezel mounted in the exemplary electronic apparatus according to the embodiment;

FIG. 6 is an exploded view illustrating the component configuration of the front bezel mounted in the exemplary electronic apparatus according to the embodiment;

FIGS. 7A and 7B are each an illustration depicting opening and closing of a shutter in the front bezel of the exemplary electronic apparatus according to the embodiment;

FIGS. 8A and 8B are each an illustration depicting opening and closing of a shutter in the front bezel of the exemplary electronic apparatus according to the embodiment;

FIG. 9 is an illustration depicting the configuration of a shutter opening and closing mechanism in the front bezel of the exemplary electronic apparatus according to the embodiment;

FIG. 10 is an exploded perspective view illustrating the configuration of a filter vibration mechanism in the front bezel of the exemplary electronic apparatus according to the embodiment;

FIG. 11 is a front view illustrating the configuration of the filter vibration mechanism in the front bezel of the exemplary electronic apparatus according to the embodiment;

FIGS. 12A to 12E are illustrations depicting the operation of the filter vibration mechanism in the front bezel of the exemplary electronic apparatus according to the embodiment; and

FIG. 13 is a flow chart describing a method of cleaning a filter in the exemplary electronic apparatus according to the embodiment.

### DESCRIPTION OF EMBODIMENT

Hereinafter, an embodiment according to the present electronic apparatus and filter device will described with reference to the accompanying drawings. However, the embodiment below is presented by way of example only, and it is not intended to exclude various modifications and technical applications which are not explicitly stated in the embodiment. That is, various modifications of the present embodiment may be implemented without departing from the scope of the gist of the present embodiment. Each figure is not intended to suggest that the present embodiment includes the illustrated components only but may include other functions.

(A) Configuration

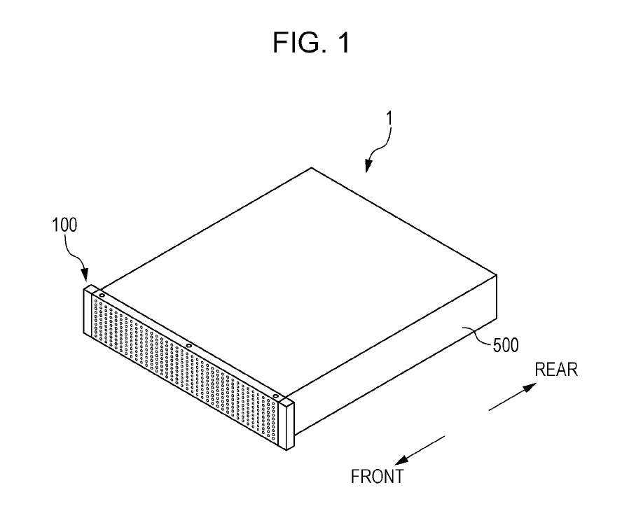

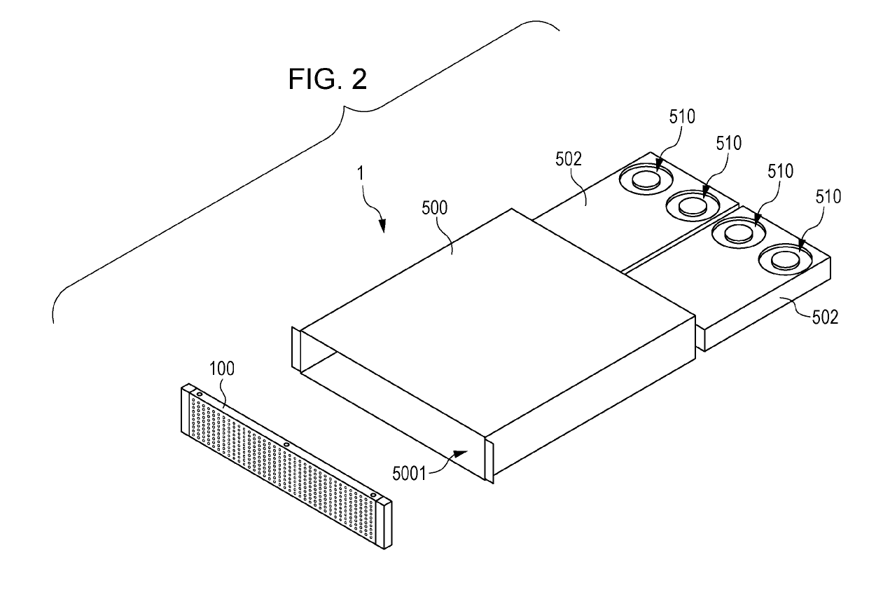

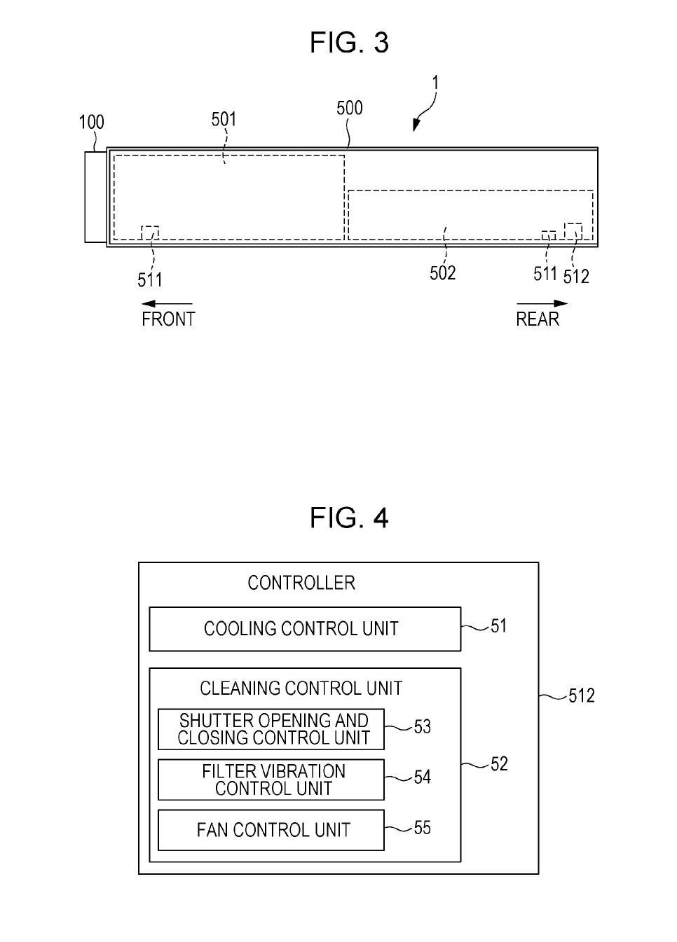

FIG. 1 is a perspective view schematically illustrating the appearance of an exemplary electronic apparatus 1 according to an embodiment, FIG. 2 is an exploded perspective view schematically illustrating the internal configuration of the electronic apparatus 1, and FIG. 3 is a side view of the electronic apparatus 1.

As illustrated in FIGS. 1 to 3, the electronic apparatus 1 includes a box-shaped housing 500 within which an electronic component 501, cooling fan attached units 502, and other components are disposed.

The electronic component 501 includes a hard disk, its control circuit, and a power supply that supplies power to the hard disk and the control circuit.

Hereinafter, an exemplary will be presented in which the electronic apparatus 1 is a storage device including a hard disk as the electronic component 501. The hard disk and the control circuit operate with the power supplied from the power supply.

The present electronic apparatus 1 is used for a mission critical task for which the electronic apparatus 1 is normally not allowed to be stopped. The present electronic apparatus 1 is installed in a computer room, for example. In a computer room, a great number of servers and storage devices are installed. In order to achieve stable operation of these devices in a great number, air conditioning in the computer room has stronger setting than that in a normal office environment, and the computer room is designed to have active air circulation. However, unlike a clean room where semiconductors are manufactured, dust protection measures are not particularly taken for a computer room, and thus the computer room inevitably contains more dirt and dust from the outside than in a normal office environment. For this reason, it is inevitable that dirt and dust intrude into the devices.

However, the electronic apparatus 1 is not limited to a storage device and may include other electronic components as the electronic component 501 except for a hard disk and its control circuit.

Heat is generated as the electronic component 501 operates, and the electronic component 501 is cooled by cooling air which is blown by cooling fans 510 of the cooling fan attached units 502. That is, the electronic component 501 corresponds to an object to be cooled disposed in the housing 500.

The housing 500 has a face through which an opening 5001 is formed, and a front bezel 100 (an exemplary filter device) is attached to the face so as to close the opening 5001. The front bezel 100 is removably attached to the housing 500.

Hereinafter, for the sake of convenience, one side of the housing 500, to which the front bezel 100 is attached, is referred to as the front side, and the other side of the housing 500, which is opposed to the front bezel 100, is referred to as the rear side.

A flow rate sensor 511 is disposed at each of predetermined positions in the housing 500. The flow rate sensor 511 is a sensor that measures a flow rate of air and transmits a result of the measurement to a controller 512 of a cooling fan attached unit 502, for example. It is to be noted that various known sensors may be used as the flow rate sensor 511 and a detailed description will be omitted. The flow rate sensor 511 may transmit a measurement result to other functional unit such as a control circuit of a hard disk which is not illustrated.

In the example illustrated in FIG. 3, the flow rate sensor 511 is disposed at each of two positions on the front side and the rear side in the housing 500, and each flow rate sensor 511 transmits a measurement result to the controller 512.

The number and positions of the flow rate sensor 511 disposed in the housing 500 are not limited to these, and various modifications of the present embodiment may be implemented.

In the housing 500, as described below, driving the cooling fans 510 causes air (cooling air) to pass through the front bezel 100 and flow in through the opening 5001 of the housing 500. Then the cooling air, which has flowed into the housing 500, passes along the periphery of the electronic component 501, then flows out through an opening (not illustrated) which is formed on the rear side of the housing 500.

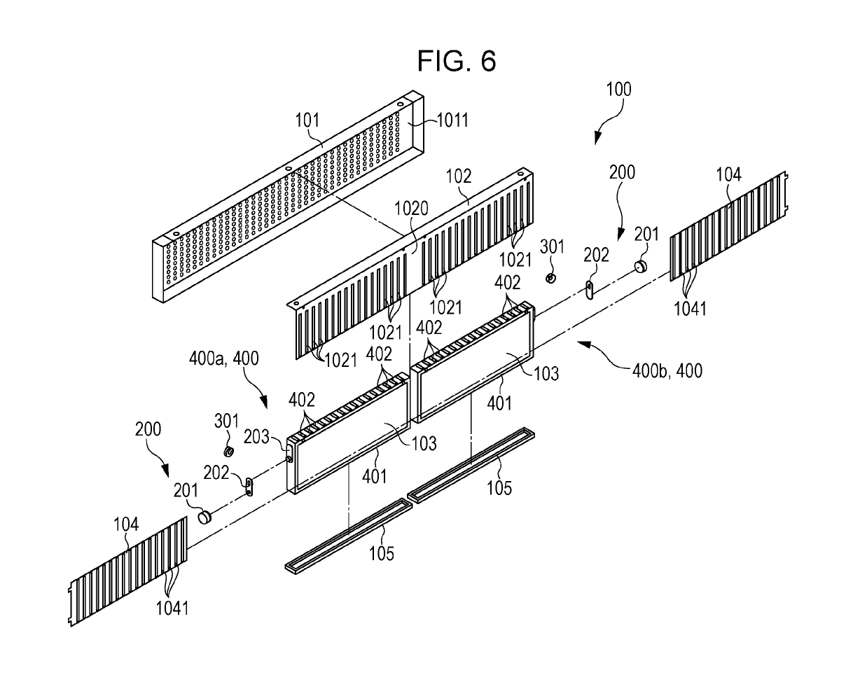

As described below, the front bezel 100 is equipped with filters 103 (see FIG. 6) that remove foreign matters in the passing cooling air. In the case where a filter 103 is clogged, the flow rate of the cooling air flowed into the housing 500 is reduced, and thus a flow rate value measured by the flow rate sensor 511 is also reduced. Consequently, clogging of each filter 103 may be detected based on the measurement result of the flow rate sensor 511.

In the housing 500, as illustrated in FIG. 3, the electronic component 501 is disposed on the front side, and the cooling fan attached units 502 are disposed on the rear side. However, disposition of the electronic component 501 in the housing 500 is not limited to this, and various modifications of the present embodiment may be implemented, for example, the electronic component 501 may be disposed on the rear side in the housing 500.

Each cooling fan attached unit 502 includes the cooling fans 510 and the controller 512. Each cooling fan 510 is a device that sends air and includes a fan and a motor which are not illustrated. The cooling fan 510 is, for example, a multi-blade centrifugal fan, and is formed by radially disposing a plurality of blades around the rotation shaft which is rotationally driven by a motor.

In the cooling fan 510, rotational driving of the fan by the motor generates air (cooling air) which passes through the front bezel 100 and flows in through the opening 5001 of the housing 500.

Then the cooling air, which has flowed into the housing 500, passes along the periphery of the electronic component 501, then flows out through an opening (not illustrated) which is formed on the rear side of the housing 500. The cooling air, when passing along the periphery of the electronic component 501, cools the electronic component 501 by absorbing heat therefrom.

That is, the cooling fan 510 functions as an air flow generation unit that generates cooling air which flows in the housing 500 through the opening 5001 and flows to the electronic component 501 which is an object to be cooled.

The controller 512 controls cooling of the electronic component 501 in the present electronic apparatus 1 and cleaning of the filters 103 of the front bezel 100.

FIG. 4 is a diagram illustrating the functional configuration of the controller 512 in the exemplary electronic apparatus 1 according to the embodiment.

The controller 512 performs various control operations related to cooling of the electronic component 501, and has functions as a cooling control unit 51 and a cleaning control unit 52 as illustrated in FIG. 4.

The cooling control unit 51 controls cooling of the electronic component 501 in the present electronic apparatus 1. The cooling control unit 51 changes, for example, the rotational speed of the motor of the cooling fan 510, thereby controlling the flow rate of cooling air for increase and decrease, the cooling air being generated by the cooling fan 510. For example, the cooling control unit 51 increases the flow rate of cooling air by increasing the rotational speed of the motor of the cooling fan 510.

Increase in the flow rate of cooling air enables the temperature in the housing 500 to be reduced. For example, when a temperature measured by a temperature sensor (not illustrated) disposed in the housing 500 is higher than a predetermined threshold value, the cooling control unit 51 controls the motor of the cooling fan 510 to increase the rotational speed thereof. In this manner, the cooling control unit 51 controls the temperature in the housing 500 at a level lower than or equal to the predetermined threshold value.

On the other hand, when the temperature in the housing 500 is lower than the predetermined threshold value, the controller 512 controls the motor of the cooling fan 510 to reduce the rotational speed and/or stop the rotation temporarily. In this manner, the power consumption may be reduced.

The cleaning control unit 52 controls cleaning of a filter 103 (see FIG. 6) provided in the front bezel 100.

The cleaning control unit (detection unit) 52 detects clogging of the filter 103 based on a measurement result notified from the flow rate sensor 511. For example, the cleaning control unit 52 detects clogging of the filter 103 when detecting that a measurement value from the flow rate sensor 511 is less than or equal to a predetermined threshold value. It is to be noted that the method of detecting clogging of the filter 103 is not limited to this, and various modifications of the present embodiment may be implemented. For example, the cleaning control unit 52 may detect clogging of the filter 103 when the value of the flow rate measured by the flow rate sensor 511 is compared with the value of previously measured flow rate and it is detected that the flow rate has been reduced by a predetermined threshold value or higher. In addition, the cleaning control unit 52 may detect clogging of the filter 103 based on an elapsed time since the time of previous cleaning of the filter 103, for example.

Upon detecting clogging of the filter 103, the cleaning control unit 52 starts cleaning of the filter 103 of a filter unit 400. The filter unit 400 includes the filter 103 and a filter frame 401 in which the filter 103 is provided.

The cleaning control unit 52 separately cleans a plurality of filter units 400 provided in the front bezel 100. That is, the cleaning control unit 52 selects one of the two filter units 400 provided in the front bezel 100, and cleans the filter 103 of the selected filter unit 400. Hereinafter, the filter unit 400 which is to be cleaned may be referred to as a filter unit 400 to be cleaned. Also, the filter 103 provided in a filter unit 400 which is to be cleaned may be referred to as a filter 103 to be cleaned.

As illustrated in FIG. 4, the cleaning control unit 52 has functions as a shutter opening and closing control unit 53, a filter vibration control unit 54, and a fan control unit 55.

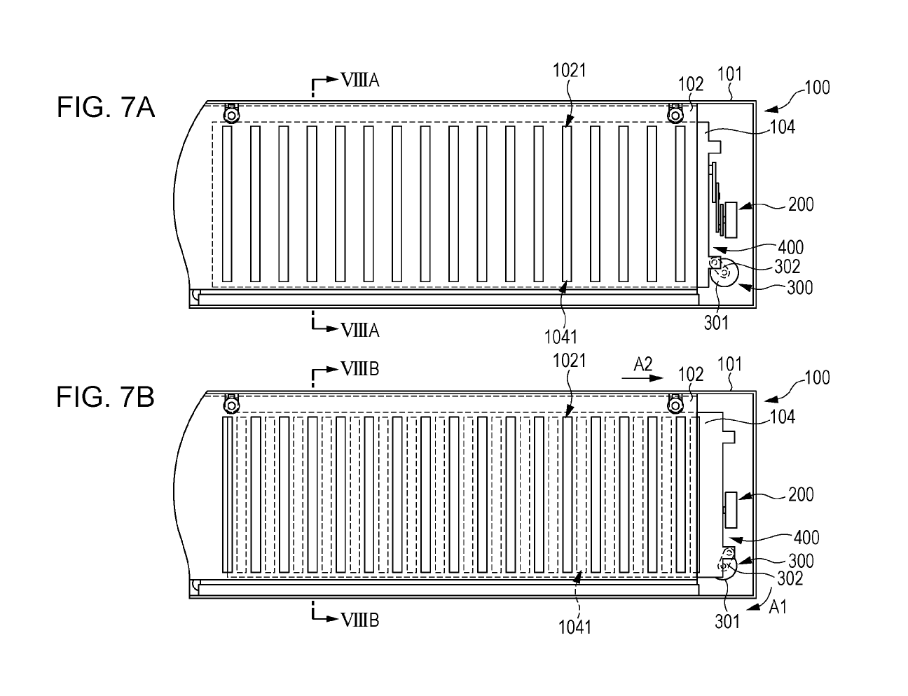

The shutter opening and closing control unit 53 controls the later-described shutter opening and closing mechanism 300 (see FIGS. 7A and 7B) provided in the front bezel 100 to switch between an open state and a closed state of a shutter 104 which is disposed along a filter 103.

The shutter opening and closing mechanism 300 is a mechanism that causes the shutter 104 disposed along the filter 103 to be moved (opened or closed). An open state of the shutter 104 set by the shutter opening and closing mechanism 300 allows cooling air to pass through the filter 103 and to flow into the housing 500. A closed state of the shutter 104 set by the shutter opening and closing mechanism 300 does not allow cooling air to pass through the filter 103 and to flow into the housing 500. The details of the shutter opening and closing mechanism 300 will be described later.

The front bezel 100 provided in the present electronic apparatus 1 is provided with a plurality of (two in the present embodiment, see FIG. 6) filters 103, and a shutter 104 is attached to each of the filters 103.

When the later-described filter vibration control unit 54 vibrates and cleans the filter 103, the shutter opening and closing control unit 53 sets a shutter 104 in a closed state, the shutter 104 corresponding to the filter 103 to be cleaned. At this point, the shutter opening and closing control unit 53 sets a shutter 104 in an open state, the shutter 104 corresponding to the filter 103 (non-cleaning object) which is not to be cleaned.

The filter vibration control unit 54 controls the later-described filter vibration mechanism 200 (see FIG. 10) provided in the front bezel 100, and cleans the filter 103 by vibrating the filter unit 400.

The filter vibration mechanism 200 causes the filter unit 400 (filter 103) to move (vibrate) back and forth continuously in a predetermined direction (for example, in a vertical direction), thereby causing a foreign matter such as dirt or dust adhering to the filter 103 to be dropped and removed. The filter vibration mechanism 200 functions as a cleaning processing unit.

As described above, the front bezel 100 provided in the present electronic apparatus 1 includes a plurality of filters 103, and the filter vibration mechanism 200 vibrates the plurality of filters 103 separately. That is, the filter vibration mechanism 200 vibrates only the filter 103 to be cleaned and clean it, and does not vibrate the filter 103 (non-cleaning object) which is not to be cleaned. The details of the filter vibration mechanism 200 will be described later.

The fan control unit 55 controls the rotational speed of the motor of the cooling fan 510, thereby controlling the flow rate of cooling air for increase and decrease, the cooling air being generated by the cooling fan 510. For example, while the above-described shutter opening and closing control unit 53 keeps a shutter 104 corresponding to a filter 103 to be cleaned in a closed state, the fan control unit 55 increases the flow rate of cooling air by increasing the rotational speed of the motor of the cooling fan 510.

That is, the fan control unit 55 increases the flow rate of cooling air by increasing the rotational speed of the motor of the cooling fan 510 while the above-described filter vibration control unit 54 vibrates the filter 103 to clean it.

A closed state of the shutter 104 corresponding to the filter 103 to be cleaned does not allow cooling air to flow in via the filter 103, and the flow rate of cooling air flowing into the housing 500 is decreased. Thus, while a shutter 104 corresponding to a filter 103 to be cleaned is kept in a closed state, the fan control unit 55 increases the rotational speed of the motor of the cooling fan 510, thereby increasing the flow rate of cooling air that flows in via a filter 103 which is not to be cleaned. Accordingly, the flow rate of cooling air flowing into the housing 500 is maintained to approximately the same level as before the cleaning of the filter 103, and thus cooling performance of the electronic component 501 is maintained.

In this manner, the fan control unit 55 functions as a flow rate increase control unit that controls the motor of the cooling fan 510 to increase the flow rate of cooling air.

It is to be noted that each of the functions of the controller 512 described above may be implemented as, for example, a circuit component (control chip) that is designed to achieve the function, or implemented by a processor (computer) that executes a program, the processor being not illustrated, and various modifications of the present embodiment may be implemented.

In the case where each function of the controller 512 is achieved by a processor that executes a program, the programs for achieving the functions of the cooling control unit 51 and the cleaning control unit 52 are provided as a form that is recorded on a computer-readable recording medium including, for example, a flexible disk, CD (such as CD-ROM, CD-R, CD-RW), DVD (such as DVD-ROM, DVD-RAM, DVD-R, DVD+R, DVD-RW, DVD+RW, HD DVD), a Blu-ray disc, a magnetic disk, an optical disc, and a magneto-optical disc. A computer then reads a program from the storage medium and transfers the program to an internal storage device or an external storage device to be stored, and uses the program. The program may be recorded, for example, on a storage device (storage medium) such as a magnetic disk, an optical disc, or a magneto-optical disc, and may be provided to a computer via a communication channel from the storage device.

When each function of the cooling control unit 51 and the cleaning control unit 52 is achieved, a program stored in an internal storage device (a random access memory (RAM) or a read only memory (ROM) which is not illustrated in the present embodiment) is executed by a microprocessor (central processing unit (CPU)) or the like of a computer. In this process, a program recorded on a storage medium may be read and executed by a computer.

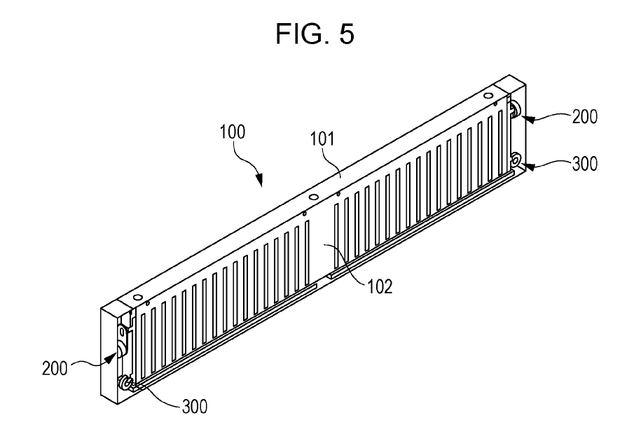

Next, the shutter opening and closing mechanism 300 will be described with reference to FIGS. 5 to 8B.

FIG. 5 is a perspective view illustrating the appearance of the front bezel 100 mounted in the exemplary electronic apparatus 1 according to the embodiment, and FIG. 6 is an exploded view illustrating the component configuration of the front bezel 100. It is to be noted that FIGS. 5 and 6 illustrate a rear view (that is, the rear side) of the front bezel 100 as seen from the housing 500.

As illustrated in FIGS. 5 and 6, the front bezel 100 includes a case 101, a stay 102, the shutters 104, trays 105, the filter vibration mechanisms 200, the shutter opening and closing mechanisms 300, and the filter units 400.

As illustrated in FIGS. 5 and 6, the front bezel 100 includes a plurality of (two in the example illustrated in FIG. 6) filter units 400a, 400b between the case 101 and the stay 102.

The case 101 has a rectangular base portion 1011, and forms a tray shape in which the surrounding four sides of the base portion 1011 serve as upright bent portions. The base portion 1011 of the case 101 is similar to the opening 5001 of the housing 500 in a size which is approximately the same as or slightly larger than the size of the opening 5001.

Hereinafter, for the sake of convenience, the longitudinal direction of the base portion 1011 of the case 101 is referred to as the crosswise direction, and the transverse direction is referred to as the vertical direction.

The stay 102 has a base portion 1020 that is approximately similar to the above-described base portion 1011 of the case 101, and forms a tray shape in which one side in the longitudinal direction of the surrounding four sides of the base portion 1020 serves as an upright bent portion. The stay 102 is formed in an L-shape and covers the filter units 400 and the shatters 104.

Then a plurality of filter units 400a, 400b (filter 103) are disposed so as to be interposed between the base portion 1011 of the case 101 and the base portion 1020 of the stay 102.

Specifically, two plate-shaped filter units 400 are disposed side-by-side in the crosswise direction of the case 101 so as to equally divide the base portion 1011 of the case 101. Thus, with the front bezel 100 attached to the opening 5001 of the housing 500, the opening 5001 is closed by the two filter units 400a, 400b proportionally in a crosswise direction.

The filter units 400a and 400b have a similar configuration. Hereinafter, to identify one of the plurality of filter units, the symbol 400a or 400b is used as the symbol indicating a filter unit. When any filter unit is mentioned, however, the symbol 400 is used.

The filter unit 400 includes the filter 103 and the filter frame 401. The filter 103 removes a foreign matter contained in cooling air and does not allow a foreign matter to intrude into the housing 500 while allowing the cooling air to pass through but not allowing a foreign matter to pass through, the foreign matter having a predetermined size, such as dust contained in the cooling air. A foreign matter, which is not allowed to pass through, adheres to the filter 103.

The filter 103 has a rectangular plate-like shape and its perimeter is surrounded by the filter frame 401.

Openings 1021 are formed in the base portion 1020 of the stay 102, at positions adjacent to the filter 103. In the example illustrated in FIG. 6 and other Figures, slits are formed in the base portion 1020 as the openings 1021, the slits extending in the vertical direction. The slit-shaped openings 1021 are continuously formed in the base portion 1020 in the crosswise direction. It is to be noted that the plurality of openings 1021 is formed at regular intervals in the base portion 1020 in the crosswise direction.

Openings are also formed in the base portion 1011 of the case 101 at positions opposite to the openings 1021 of the base portion 1020 of the stay 102 with respect to the filter 103. In the example illustrated in FIG. 6, openings are disposed in the base portion 1011 of the case 101 at positions opposed to the openings 1021 formed in the base portion 1020 of the stay 102, the openings in the base portion 1011 being formed by arranging circular holes in the vertical direction.

Thus, in the front bezel 100, cooling air, which has flowed in through the openings formed in the base portion 1011 of the case 101, passes through the filter 103 and flows out through the openings 1021 formed in the base portion 1020 of the stay 102.

However, the shapes of the openings of the base portion 1011 of the case 101 and of the openings 1021 of the base portion 1020 of the stay 102 are not limited to the shapes illustrated in FIG. 6, and various modifications of the present embodiment may be implemented. For example, slits similar to the openings 1021 of the base portion 1020 of the stay 102 may be formed as the openings of the base portion 1011 of the case 101, or similarly to the openings of the base portion 1011 of the case 101, vertically arranged circular holes may be formed as the openings 1021 of the base portion 1020 of the stay 102.

In the front bezel 100, the respective shutters 104 are disposed between the filter units 400 and the stay 102.

Each shutter 104 is a rectangular plate-like member having approximately the same size as the filter 103, and has openings 1041 similar to the openings 1021 of the base portion 1020 of the stay 102. The shutter 104 is disposed on a rail (not illustrated) between the filter unit 400 and the stay 102, and is designed to be slidable by the later-described shutter opening and closing mechanism 300 in the crosswise direction. The shutter opening and closing mechanism 300 causes the shutter 104 to move in the crosswise direction, thereby selectively placing the shutter 104 at a first position or a second position between the filter unit 400 and the stay 102. The shutter opening and closing mechanism 300 functions as a moving mechanism for the shutter 104.

In a state where the shutter 104 is at the first position, the openings 1021 of the stay 102 and the openings 1041 of the shutter 104 communicate with each other, so that the front bezel 100 allows cooling air to pass therethrough.

In a state where the shutter 104 is at the second position, the openings 1021 of the stay 102 are opposed to the area in the shutter 104, other than the openings 1041, so that the openings 1021 are closed. In this manner, the shutter 104 does not allow cooling air to flow through the front bezel 100.

The area in the shutter 104, other than the openings 1041 functions as a closure portion that closes the openings 1021 of the stay 102. It is to be noted that in the shutter 104, the openings 1041 are formed in the crosswise direction with the same pitch as the pitch of the openings 1021 formed in the stay 102.

In the shutter 104, the interval between adjacent openings 1041 is made wider than the length (width) of each opening 1021 of the base portion 1020 of the stay 102 in the crosswise direction.

In this manner, the stay 102 is disposed on flow paths of cooling air, and functions as a first blocking member that has the openings 1021. The shutter 104 is disposed on the flow paths of cooling air, and functions as a second blocking member that has the openings 1041 and a closure portion. The stay 102, the shutter 104, and the shutter opening and closing mechanism 300 function as blocking units. Hereinafter, a state where the shutter 104 is at the first position is referred to as an open state of the shutter 104, and a state where the shutter 104 is at the second position is referred to as a closed state of the shutter 104.

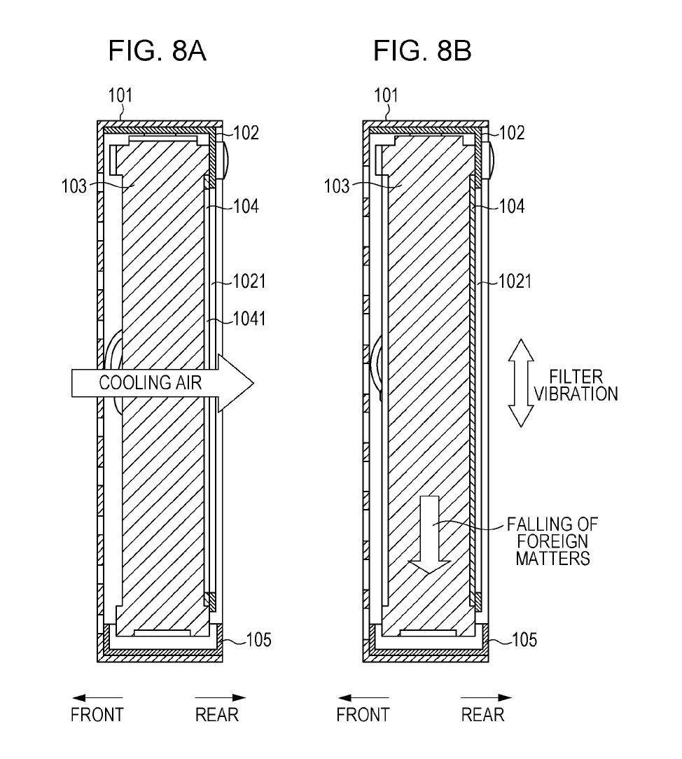

FIGS. 7A and 7B and FIGS. 8A and 8B are each an illustration depicting opening and closing of the shutter 104 in the front bezel 100 of the exemplary electronic apparatus according to the embodiment, FIGS. 7A and 7B are each a rear view seen from the rear side of the front bezel 100, and FIGS. 8A and 8B are each a cross-sectional side view of the front bezel 100. FIGS. 7A and 8A each indicate an open state of the shutter 104, and FIGS. 7B and 8B each indicate a closed state of the shutter 104.

As illustrated in FIGS. 7A and 8A, each opening 1041 of the shutter 104 is opposed to a corresponding opening 1021 formed in the base portion 1020 of the stay 102 at the first position (open state). Consequently, in a state where the shutter 104 is at the first position, the openings formed in the base portion 1011 of the case 101, the openings 1021 formed in the base portion 1020 of the stay 102, and the openings 1041 of the shutter 104 communicate with one another in the front bezel 100. That is, in the front bezel 100, cooling air, which has flowed in through the openings formed in the base portion 1011 of the case 101, passes through the filter 103, passes through the openings 1021 formed in the base portion 1020 of the stay 102, further passes through the openings 1041 of the shutter 104, and flows into the housing 500.

When a motor 301 is rotated in the direction of arrow A1 in a state where the shutter 104 is at the first position as illustrated in FIG. 7B, the shutter 104 is moved in the direction of arrow A2 and is moved to the second position (closed state) as illustrated in FIGS. 7B and 8B.

As illustrated in FIGS. 7B and 8B, at the second position, the openings 1021 formed in the base portion 1020 of the stay 102 are opposed to the area of the shutter 104, in which the openings 1041 are not formed, and each opening 1021 is thereby closed by the shutter 104.

That is, in a state where the shutter 104 is at the second position, in the front bezel 100, cooling air, which has flowed in through the openings formed in the base portion 1011 of the case 101 and passes through the filter 103 and the openings 1021 of the stay 102, is blocked by the shutter 104 and unable to flow in the housing 500.

Thus, as described above, in the shutter 104, the interval between adjacent openings 1041 is made wider than the length (width) of each opening 1021 of the base portion 1020 of the stay 102 in the crosswise direction as illustrated in FIG. 7B.

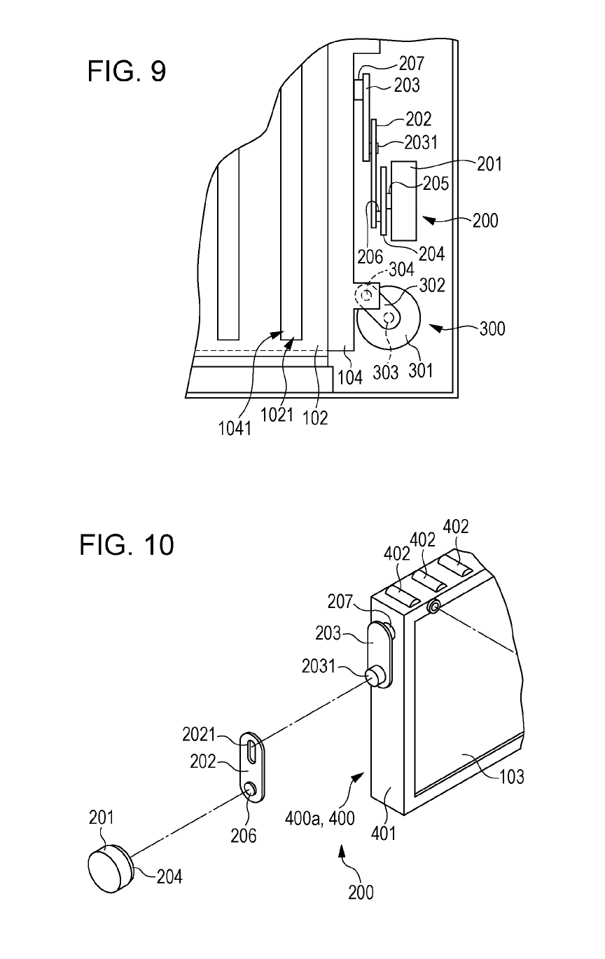

FIG. 9 is an illustration depicting the configuration of a shutter opening and closing mechanism 300 of the front bezel 100 of the exemplary electronic apparatus 1 according to the embodiment. It is to be noted that the configuration of the later-described filter vibration mechanism 200 is also illustrated in FIG. 9.

The shutter opening and closing mechanism 300 includes the motor 301 and a link 302 as illustrated in FIG. 9. In the motor 301, a motor shaft 303 is disposed in the front-rear direction of the front bezel 100, and one end of the link 302 is fixed to the motor shaft 303. The other end of the link 302 is pivotally supported by an end of the shutter 104 via a pin 304.

Thus, when the motor 301 is rotated in the forward direction and the reverse direction, the other end of the link 302 rotates and moves in a crosswise direction according to the rotation of the motor shaft 303, and the shutter 104 is moved in the crosswise direction. That is, the shutter 104 may be placed at any position in an open state and a closed state by rotating the motor 301 then stopping the motor 301 at any position. The rotation of the motor 301 is controlled by the shutter opening and closing control unit 53 described above. It is desirable that for example, a stepping motor be used as the motor 301.

Each of the filter units 400 is provided with the shutter opening and closing mechanism 300, and thus two shutters 104 provided in the front bezel 100 are able to open or close the respective filters 103 independently.

The shutter opening and closing control unit 53 controls one of two shutters 104 provided in the front bezel 100 so that the one shutter 104 is set in a closed state, the one shutter 104 being of the filter unit 400 for which the filter 103 is cleaned.

Next, the configuration of the filter vibration mechanism 200 will be described.

The filter vibration mechanism 200 vibrates the filter unit 400, thereby achieving filter cleaning by which foreign matters adhering to the filter 103 are removed from the filter 103.

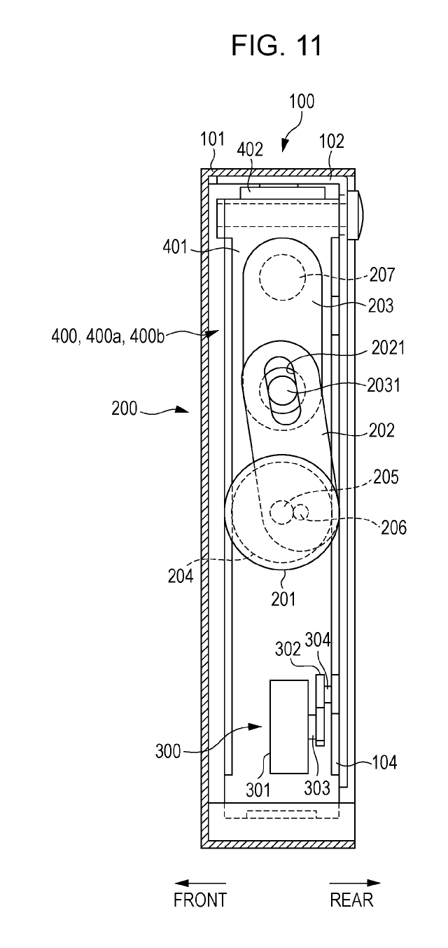

FIG. 10 is an exploded perspective view illustrating the configuration of the filter vibration mechanism 200 in the front bezel 100 of the exemplary electronic apparatus 1 according to the embodiment, and FIG. 11 is a front view of the filter vibration mechanism 200. In FIG. 9, a side view of the filter vibration mechanism 200 is also illustrated.

As illustrated in FIGS. 9 to 11, the filter vibration mechanism 200 includes a motor 201, a disk 204, a link 202, and an arm 203.

The motor 201 is disposed at an adjacent position either rightward or leftward of the filter unit 400 such that the motor shaft 205 is parallel to the crosswise direction of the front bezel 100. The disk 204 is fixed concentrically to the motor shaft 205.

One end (lower end) of the link 202 is pivotally supported by the disk 204 via a pin 206 at a position displaced from the central shaft (the motor shaft 205). That is, the disk 204 and the link 202 form a crank.

When the motor 201 is rotated in one of the forward and reverse directions, the disk 204 fixed to the motor shaft 205 rotates. Since the lower end of the link 202 is pivotally supported by the disk 204 via the pin 206, the lower end of the link 202 produces rotary motion with the motor shaft 205 of the motor 201 as the crank rotation shaft. It is to be noted that the rotation of the motor 201 is controlled by the filter vibration control unit 54 described above.

The other end (upper end) of the link 202 has a connection hole 2021 which has a longer axis in a direction in which a distance from the pin 206 increases.

An arm shaft 207 projects from each of the lateral sides of the filter frame 401 of the filter unit 400 in the crosswise direction, and one end of the arm 203 is fixed to the arm shaft 207. The arm 203 is disposed in the vertical direction of the filter frame 401, and a connection projection 2031 projects from the other end of the arm 203 in the crosswise direction.

In the front bezel 100, the filter unit 400 is designed to be movable in the vertical direction with movement in the front-rear direction and the crosswise direction restrained.

The connection projection 2031 is inserted in the connection hole 2021 of the link 202, and the filter unit 400 is freely slidable with the connection projection 2031 guided in the connection hole 2021.

As described above, when the disk 204 rotates as the motor 201 rotates, the lower end of the link 202 produces rotary motion with the motor shaft 205 as the crank rotation shaft, the lower end being pivotally supported by the disk 204 via the pin 206.

On the other hand, at this point, the upper end of the link 202 produces reciprocal motion in the vertical direction while the connection projection 2031 is being guided into the connection hole 2021.

In this manner, the upper end of the link 202 is designed to produce reciprocal motion (piston motion) in the vertical direction. That is, the filter vibration mechanism 200 forms a piston crank mechanism.

When the pin 206 is at the uppermost position after some rotation of the disk 204, the link 202 is also at the uppermost position. In this state, the lower end of the connection hole 2021 is at the position at which the lower end pushes up the connection projection 2031.

Thus, the lower end of the connection hole 2021 pushes up the connection projection 2031, and accordingly, the filter unit 400 is also pushed up via the arm 203 and the arm shaft 207.

As illustrated in FIG. 10, a plurality of projections 402 are formed on the upper portion of the filter frame 401. The projections 402 are formed upward of the positions at which the filter 103 faces the openings 1021 of the stay 102 when the filter unit 400 is mounted between the case 101 and the stay 102. That is, each projection 402 is formed at a position above an area (flow area) where cooling air flows through in the filter 103 in an open state of the shutter 104. In the filter 103, many foreign matters adhere to the area where cooling air flows through.

In addition, a tray 105 is disposed at a position below a corresponding filter unit 400 in the front bezel 100. An adhesive member such as a double-sided tape is disposed on the upper surface of the tray 105.

As described below, vibration of the filter unit 400 due to the filter vibration mechanism 200 causes foreign matters adhering to the filter 103 to fall onto the tray 105 and the foreign matters stick to the adhesive member disposed on the tray 105. The foreign matters, which have fallen on the tray 105, stick to the adhesive member, and thus intrusion of the foreign matters into the housing 500 due to blowing of cooling air is protected.

The tray 105 is removable from the front bezel 100 and when the amount of foreign matters sticking to the adhesive member increases, a maintenance worker replaces the tray 105 or the adhesive member.

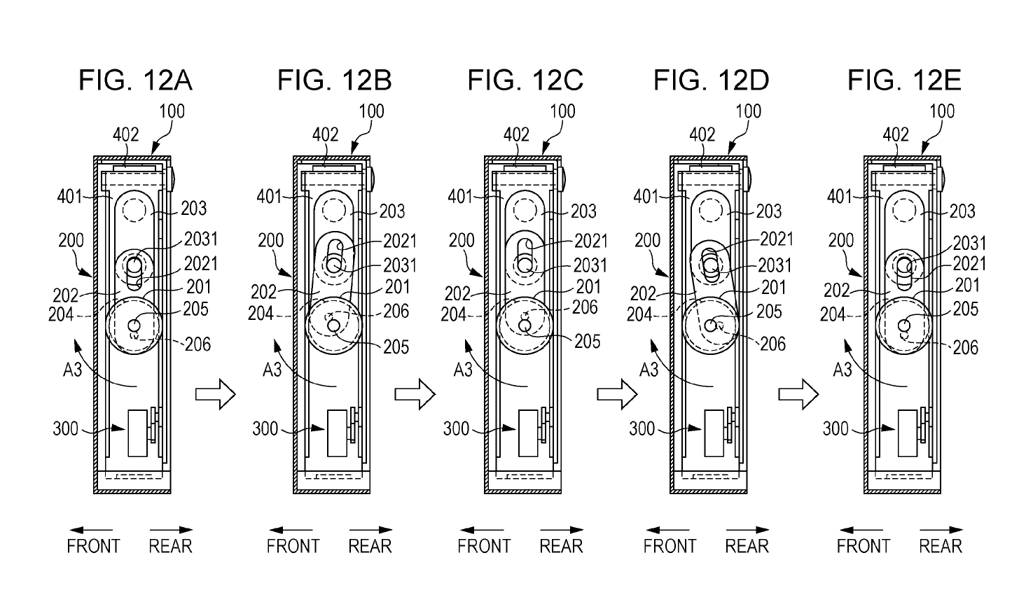

FIGS. 12A to 12E are illustrations depicting the operation of the filter vibration mechanism 200 of the front bezel 100 of the exemplary electronic apparatus 1 according to the embodiment.

FIGS. 12A and 12E each illustrate a state where the pin 206 is at the lowermost end, and FIG. 12C illustrates a state where the pin 206 is at the uppermost end. FIG. 12B illustrates a state where a transition is being made from the state illustrated in FIG. 12A to the state illustrated in FIG. 12C and FIG. 12D illustrates a state where a transition is being made from the state illustrated in FIG. 12C to the state illustrated in FIG. 12E.

That is, in the example illustrated in FIGS. 12A to 12E, the filter vibration mechanism 200 makes a transition in the order of A, B, C, D, and E.

When the disk 204 is rotated by the motor 201 in the direction of arrow A3 in the state illustrated in FIG. 12A, the lower end of the link 202 produces rotary motion (crank motion) with the motor shaft 205 as the axis and the link 202 moves upward as illustrated in FIG. 12B.

In the state illustrated in FIG. 12B, the connection projection 2031 of the arm 203 is in contact with the lower end of the connection hole 2021 of the link 202. When the disk 204 is further rotated by the motor 201 in the direction of arrow A3 from this state, the link 202 further moves upward, thereby lifting up the arm 203 and the filter unit 400.

In the state illustrated in FIG. 12C, the pin 206 is at the uppermost position and the filter unit 400 is also at the uppermost position. In this state, each projection 402 formed on the upper end of the filter frame 401 collides with the stay 102.

An impact caused by the collision is transmitted to the filter 103, and shakes off the foreign matters adhering to the filter 103.

That is, the projection 402 functions as an impact applying unit that applies an impact to the filter 103 at a position in the filter 103 according to vibration of the filter 103, the position corresponding to a flow area of cooling air.

When the disk 204 is further rotated by the motor 201 in the direction of arrow A3, the link 202 moves downward, and the arm 203 and the filter unit 400 also move downward.

In the state illustrated in FIG. 12D, the filter unit 400 reaches the lowermost end, and the lower end of the connection hole 2021 of the link 202 starts to leave from the connection projection 2031 of the arm 203. When the disk 204 is further rotated by the motor 201 in the direction of arrow A3 from this state, the link 202 further moves downward and the pin 206 reaches the lowermost end position as illustrated in FIG. 12E. In other words, a transition is made to the state illustrated in FIG. 12A, and subsequently, the states in FIGS. 12A to 12E are repeated.

In this manner, rotation of the motor 201 causes vertical vibration of the filter unit 400 in the filter vibration mechanism 200. Consequently, foreign matters adhering to the filter 103 are shaken off from the filter 103 and the filter 103 is cleaned. When the filter unit 400 is vibrated, each projection protruding from the upper portion of the filter frame 401 of the filter unit 400 collides with the stay 102, and an impact occurred at this moment is transmitted to the filter 103, thereby achieving efficient removal of the foreign matters from the filter 103.

It is to be noted that foreign matters, which have fallen from the filter 103, fall onto the tray 105 disposed below the filter 103. Since an adhesive member such as a double-sided tape is disposed on the tray 105, the fallen foreign matters stick to the adhesive member, and thus intrusion of foreign matters into the housing 500 due to blowing of cooling air may be avoided.

(B) Operation

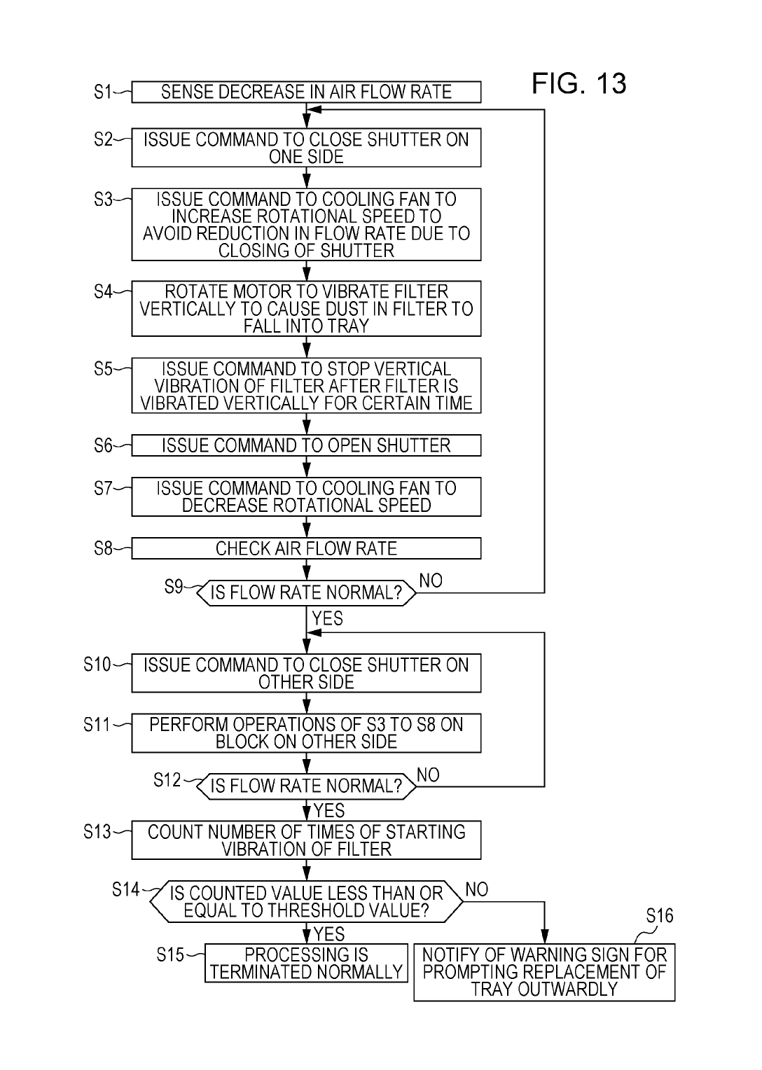

A method of cleaning the filter 103 in the exemplary electronic apparatus 1 according to the embodiment having the aforementioned configuration will be described with reference to the flow chart (steps S1 to S16) illustrated in FIG. 13.

During normal operation of the electronic apparatus 1, the shutter opening and closing control unit 53 controls the shutter opening and closing mechanism 300 to set all the shutters 104 provided in the front bezel 100 in an open state, thereby allowing cooling air to pass through the filter 103 and to flow into the housing 500.

In this state, the cooling control unit 51 of the controller 512 controls the cooling fans 510 in a predetermined rotational speed to generate cooling air in the housing 500. In the front bezel 100, cooling air, which has flowed in through the openings formed in the base portion 1011 of the case 101, passes through the filter 103, passes through the openings 1021 formed in the base portion 1020 of the stay 102, and flows into the housing 500.

The cooling air, which has flowed into the housing 500, passes along the periphery of the electronic component 501, then flows out through an opening (not illustrated) which is formed on the rear side of the housing 500. The cooling air, when passing along the periphery of the electronic component 501, absorbs heat generated from the electronic component 501 to be cooled.

In the case where cooling air, which has flowed in from the outside, contains foreign matters, the foreign matters, when passing through the inside of the front bezel 100, are caught in the filter 103, and thus intrusion of the foreign matters into the housing 500 is protected.

In the case where a filter 103 provided in the front bezel 100 is clogged, the flow rate of air in the housing 500 measured by the flow rate sensor 511 is reduced.

In step S1, the controller 512 (cleaning control unit 52) detects a decrease in the flow rate of cooling air based on a result of measurement made by the flow rate sensor 511.

In step S2, the controller 512 selects one (for example, filter unit 400a) of the two filter units 400 provided in the front bezel 100, the one filter unit being to be cleaned. The shutter opening and closing control unit 53 issues a command to a shutter opening and closing mechanism 300 to set the shutter 104 in a closed state, the shutter opening and closing mechanism 300 corresponding to the filter unit 400a to be cleaned.

According to the command, the shutter opening and closing mechanism 300 sets a shutter 104 in a closed state, the shutter 104 being provided in the filter unit 400a to be cleaned. Specifically, the shutter opening and closing control unit 53 rotates the motor 301 of the shutter opening and closing mechanism 300 by a predetermined angle, thereby moving the shutter 104 to a position for a closed state.

In step S3, the fan control unit 55 issues a command for increasing the rotational speed of the motor of the cooling fan 510, thereby increasing the flow rate of cooling air. Thus, reduction in the flow rate of cooling air is avoided, the reduction being caused by the closed state of the shutter 104 of the filter unit 400a.

In step S4, the filter vibration control unit 54 causes the filter vibration mechanism 200 to vibrate the filter unit 400a to be cleaned, thereby cleaning the filter 103. That is, rotation of the motor 201 causes vertical vibration of the filter 103, and thus foreign matters such as dirt adhering to the filter 103 are forced to fall onto the tray 105. In this process, when the filter unit 400a reaches the uppermost position, the projections 402 formed on the upper portion of the filter frame 401 collide with the stay 102, and an impact due to the collision is transmitted to the filter 103 and causes foreign matters adhering to the filter 103 to fall efficiently.

In addition, since the shutter 104 provided in the filter unit 400a to be cleaned is in a closed state, foreign matters which have fallen from the filter 103 are not allowed to intrude into the housing 500. After the filter unit 400a was vibrated continuously for a predetermined time, the filter vibration control unit 54 issues a command to the filter vibration mechanism 200 in step S5, the command for stopping the vibration of the filter unit 400a. In response to the command, rotation of the motor 201 is stopped in the filter vibration mechanism 200, and vertical movement of the filter unit 400a is stopped.

In step S6, the shutter opening and closing control unit 53 issues a command to the shutter opening and closing mechanism 300, the command for setting the shutter 104 of the filter unit 400a to be cleaned in an open state. According to the command, the shutter opening and closing control unit 53 rotates the motor 301 of the shutter opening and closing mechanism 300 by a predetermined angle in the reverse direction to the direction in step S2 described above, thereby moving the shutter 104 to a position for an open state.

In step S7, the fan control unit 55 issues a command for reducing the rotational speed of the motor of the cooling fan 510, and changes the current rotational speed back to the previous rotational speed (the predetermined rotational speed) before being increased in step S3.

In step S8, the controller 512 (cleaning control unit 52) obtains a measurement result of the flow rate of cooling air from the flow rate sensor 511, and checks the flow rate of cooling air based on the measurement result.

In step S9, it is checked whether or not the measured flow rate of cooling air is a normal value. For example, the controller 512 determines whether or not the measured flow rate of cooling air is greater than or equal to a predetermined threshold value.

When the measured flow rate of cooling air is found to be not normal as a result of checking, that is, where the measured flow rate of cooling air is less than the predetermined threshold value (see “NO” route in step S9), the operation flow returns to step S2, and the processing in steps S2 to S8 is repeatedly performed.

When the measured flow rate of cooling air is normal, that is, where the measured flow rate of cooling air is greater than or equal to the predetermined threshold value (see “YES” route in step S9), the operation flow proceeds to step S10.

In step S10, the controller 512 sets a new filter unit 400 to be cleaned, the new filter unit 400 being the filter unit 400b (on the opposite side), which was not the filter unit 400 to be cleaned in the previous processing. The shutter opening and closing control unit 53 issues a command to the shutter opening and closing mechanism 300 corresponding to the new filter unit 400b to be cleaned, the command for setting the shutter 104 in a closed state.

In step S11, the fan control unit 55, the filter vibration control unit 54, and the shutter opening and closing control unit 53 repeatedly perform the processing of steps S3 to S8 described above.

Subsequently, in step S12, it is checked whether or not the measured flow rate of cooling air is a normal value. When the measured flow rate of cooling air is found to be not normal as a result of checking, that is, where the measured flow rate of cooling air is less than the predetermined threshold value (see “NO” route in step S12), the operation flow returns to step S10.

When the measured flow rate of cooling air is normal, that is, where the measured flow rate of cooling air is greater than or equal to the predetermined threshold value (see “YES” route in step S12), the operation flow proceeds to step S13.

In step S13, the controller 512 counts the number of times of starting vibration of the filter unit 400, and in step S14, checks whether or not the counted value is greater than or equal to a predetermined threshold value.

When the counted value is less than or equal to a threshold value (see “YES” route in step S14), the processing is terminated normally in step S15. When the counted value is greater than the threshold value (see “NO” route in step S14), the controller 512 notifies of a warning sign for prompting cleaning of the tray 105 in step S16, and the processing is terminated. A maintenance worker replaces the tray 105 according to the notification. It is to be noted that the adhesive member of the tray 105 may be cleaned or replaced instead of replacing the tray 105. In this case, the filter 103 may be replaced.

In the processing described above, in the case where the flow rate of cooling air does not go back normal even after the filter 103 is cleaned for a predetermined number of times or more, cleaning of the filter 103 may be stopped and alarm may be output to urge a maintenance worker to replace the filter 103, and various modifications of the present embodiment may be implemented.

(C) Effect

In this manner, in the exemplary electronic apparatus 1 according to the embodiment, the front bezel 100 is provided with a plurality of filter units 400, and while cooling air is sucked via at least one of the filter units 400, the filter 103 of the other filter unit 400 is cleaned.

Consequently, the filter 103 may be cleaned with the electronic apparatus 1 in operation while the electronic component 501 in the housing 500 is cooled. In this process, cooling air supplied into the housing 500 is sucked via the filter 103, and thus intrusion of foreign matters contained in the cooling air into the housing 500 may be avoided.

When the filter 103 (filter 103 to be cleaned) is cleaned, the shutter opening and closing control unit 53 controls the shutter opening and closing mechanism 300 to set a shutter 104 in a closed state, the shutter 104 being attached to the filter 103 to be cleaned. Thus, intrusion of foreign matters such as dust into the housing 500 may be avoided, the foreign matters being separated from the filter 103 due to cleaning of the filter 103 to be cleaned.

Vibration of the filter unit 400 due to the filter vibration mechanism 200 causes foreign matters adhering to the filter 103 to be removed. In this process, the projections 402 formed on the upper portion of the filter frame 401 are made to collide with the stay 102 adjacent to the projections 402, then an impact caused by the collision is transmitted to the filter 103, thus it is possible to efficiently remove foreign matters from the filter 103. The projections 402 are one example of an impact applying unit. The projections 402 function as a cleaning processing unit.

The projections 402 are each formed on the upper portion of the filter frame 401, at a position above an area where cooling air flows through in the filter 103 in an open state of the shutter 104, and thus an impact is concentratedly applied to the areas to which many foreign matters adhere to the filter 103, thereby achieving efficient cleaning.

(D) Others

The technology disclosed herein is not limited to the embodiment described above, and various modifications may be made within the scope not departing from the gist of the present embodiment. Any configuration and any processing in the present embodiment may be selected according to request or combined as appropriate.

For example, in the above-described embodiment, the flow rate sensor 511 measures the flow rate of cooling air, and the controller 512 (cleaning control unit 52), after receiving a measurement result, detects clogging of the filter 103 based on the measurement result. However, the configuration is not limited to this. For example, the flow rate sensor 511 may be provided with a function of detecting a decrease in the flow rate of cooling air, and upon detecting a decrease, the flow rate sensor 511 may notify the controller 512 of the detected decrease, and thus the controller 512 may detect clogging of the filter 103.

In the above-described embodiment, the front bezel 100 is provided with two filter units 400. However, without being limited to this, the front bezel 100 may be provided with three or more filter units 400.

In this case, for at least one of the three or more filter units 400, corresponding at least one filter 103 is set in an open state to allow cooling air to pass through, and the filters 103 for the other filter units 400 are cleaned. In this process, the fan control unit 55 increases the flow rate of cooling air according to the number of the filter units 400 to be cleaned at the same time. For example, the flow rate of cooling air is increased in proportion to the number of the filter units 400 to be cleaned.

However, when the number of filter units 400 provided in the front bezel 100 is increased, the number of the filter vibration mechanisms 200 and the number of the shutter opening and closing mechanisms 300 are increased according to the number of filter units 400, and there will be a desire for a space for disposing these mechanisms. Consequently, in view of manufacturing cost and efficiency of cooling air flow, the front bezel 100 is preferably provided with two filter units 400.

Although the projections 402 are formed on the upper portion of the filter frame 401 in the above-described embodiment, the configuration is not limited to this. That is, instead of forming the projections 402 on the filter frame 401, the projections 402 may be formed on the stay 102 with which the filter frame 401 collides.

In addition, the configuration of the shutter 104 and the shutter opening and closing mechanism 300 is not limited to the configuration described in the embodiment above, and various modifications of the present embodiment may be implemented. That is, it is sufficient that a first state and a second state be selectively set, the first state allowing the openings 1041 and the openings 1021 formed in the front bezel 100 to be released, the second state allowing the openings 1041 or the openings 1021 to be blocked.

The configuration of the filter vibration mechanism 200 is not limited to the configuration described in the embodiment above, and various modifications of the present embodiment may be implemented. That is, various mechanisms for vibrating the filter unit 400 may be used as the filter vibration mechanism 200.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. An electronic apparatus comprising:
a housing including an opening;
an object to be cooled that is disposed in the housing;
an air flow generation unit that generates cooling air which flows through the opening into the housing and flows to the object to be cooled;
a plurality of filter units that remove a foreign matter contained in the cooling air;
a blocking unit that blocks at least one filter unit to be cleaned, among the filter units;
a controller that increases a flow rate of the cooling air using the air flow generation unit; and
a cleaning processing unit that cleans the filter unit to be cleaned, the filter unit to be cleaned being blocked by the blocking unit.

2. The electronic apparatus according to claim 1,
wherein the cleaning processing unit includes a vibration mechanism that vibrates the filter unit to be cleaned.

3. The electronic apparatus according to claim 2, further comprising an impact applying unit, disposed at a position corresponding to a flow path of the cooling air in the filter unit to be cleaned, that applies an impact to the filter unit to be cleaned in response to vibration of the filter unit to be cleaned.

4. The electronic apparatus according to claim 1,
wherein the blocking unit includes:
first and second blocking members disposed on a flow path of the cooling air, the first blocking member having an opening, the second blocking member having an opening and a closure portion; and
a moving mechanism that causes the second blocking member to be selectively placed at one of a first position and a second position, the first position allowing the opening of the second blocking member and the opening of the first blocking member to communicate with each other, the second position allowing the closure portion of the second blocking member to be opposed to the opening of the first blocking member to close the opening of the first blocking member.

5. The electronic apparatus according to claim 4, further comprising
a flow rate sensor, disposed in the housing, to measure a flow rate of the cooling air,
wherein
the electronic apparatus includes a plurality of the second blocking members,
the air flow generation unit is a cooling fan,
each filter unit includes a projection,
the cleaning processing unit includes a vibration mechanism that vibrates the filter unit to be cleaned, and
the controller:
determines whether the flow rate of the cooling air decreases using the flow rate sensor,
selects the filter unit to be cleaned from among the filter units when determining that the flow rate of the cooling air decreases,
moves at least one of the second blocking members, which corresponds to the selected filter unit to be cleaned, to the second position using the moving mechanism,
increases a rotational speed of the cooling fan from a predetermined rotational speed to increase the flow rate of the cooling air,
vibrates the selected filter unit to be cleaned in vertical direction for a predetermined time so that the projection of the selected filter unit to be cleaned collides with the first blocking member using the vibration mechanism,
moves the at least one of the second blocking members, which corresponds to the selected filter unit to be cleaned, to the first position using the moving mechanism,
changes the increased rotational speed of the cooling fan to the predetermined rotational speed, and
determines whether the flow rate of the cooling air is greater than or equal to a given value.

6. A filter device comprising:
a plurality of filter units that are removably attached to an opening provided in a housing of an electronic apparatus and remove a foreign matter from cooling air that flows to an object to be cooled disposed in the housing from the opening of the housing;
a blocking unit that blocks at least one filter unit to be cleaned, among the filter units; and
a cleaning processing unit that cleans the filter unit to be cleaned which is blocked by the blocking unit.

7. The filter device according to claim 6,
wherein the cleaning processing unit includes a vibration mechanism that vibrates the filter unit to be cleaned.

8. The filter device according to claim 7, further comprising
an impact applying unit, disposed at a position corresponding to a flow path of the cooling air in the filter unit to be cleaned, that applies an impact to the filter unit to be cleaned in response to vibration of the filter unit to be cleaned.

9. The filter device according to claim 6,
wherein the blocking unit includes:
first and second blocking members disposed on a flow path of the cooling air, the first blocking member having an opening, the second blocking member having an opening and a closure portion; and
a moving mechanism that causes the second blocking member to be selectively placed at one of a first position and a second position, the first position allowing the opening of the second blocking member and the opening of the first blocking member to communicate with each other, the second position allowing the closure portion of the second blocking member to be opposed to the opening of the first blocking member to close the opening of the first blocking member.
